(19) United States
(12) Patent Application Publication
(10) Pub. No.: US 2025/0102914 A1
(43) Pub. Date: Mar. 27, 2025

(54) PHOTORESIST COMPOSITIONS INCLUDING A SULFONATE GROUP AND METHODS OF MANUFACTURING INTEGRATED CIRCUIT DEVICES USING THE SAME

(71) Applicant: Samsung Electronics Co., Ltd., Suwon-si (KR)

(72) Inventors: Honggu Im, Suwon-si (KR); Yonghoon Moon, Suwon-si (KR); Jeongju Park, Suwon-si (KR); Jicheol Park, Suwon-si (KR); Giyoung Song, Suwon-si (KR)

(21) Appl. No.: 18/639,380

(22) Filed: Apr. 18, 2024

(30) Foreign Application Priority Data
Sep. 27, 2023 (KR) 10-2023-0131170

(51) Int. Cl. G03F 7/039; C08F 212/14; C08F 220/38; C08F 228/02; G03F 7/038; H01L 21/027

(52) U.S. Cl. CPC G03F 7/039; C08F 212/30; C08F 220/382; C08F 228/02; G03F 7/038; H01L 21/0274

(57) ABSTRACT

Photoresist compositions and methods of manufacturing an integrated circuit device by using said photoresist compositions are described. The photoresist compositions may include a photosensitive polymer, a photoacid generator (PAG), and a solvent, wherein the photosensitive polymer contains a sulfonate group (—SO₂O—) bonded with an α-trifluoromethylbenzyl group.

### CROSS-REFERENCE TO RELATED APPLICATION

This application claims priority under 35 U.S.C. § 119 to Korean Patent Application No. 10-2023-0131170, filed on Sep. 27, 2023, in the Korean Intellectual Property Office, the disclosure of which is incorporated by reference herein in its entirety.

### FIELD

The present invention relates to photoresist compositions and methods of manufacturing an integrated circuit device using the same, and more particularly relates to photoresist compositions including a sulfonate group functional group, and methods of manufacturing an integrated circuit device by using said photoresist compositions.

### BACKGROUND

Due to the development of electronic technology, down-scaling of semiconductor devices has been progressing rapidly in recent years. As a result, a photolithography process that is advantageous for implementing fine patterns is desired. Particularly, in a photolithography process for manufacturing an integrated circuit device, the development of technology that may increase light sensitivity and improve dissolution contrast between an exposed region and a non-exposed region of a photoresist film with respect to a developing solution is desired.

### SUMMARY

The present invention provides a photoresist composition that may improve dissolution contrast (e.g., to a developing solution) between an exposed region and a non-exposed region of a photoresist film during a photolithography process for manufacturing an integrated circuit device.

The present invention also provides methods of manufacturing an integrated circuit device that may improve dissolution contrast between an exposed region and a non-exposed region of a photoresist film, which thereby may increase the dimensional precision of patterns later formed during a photolithography process for manufacturing an integrated circuit device using the photoresist film.

Also, the objects of the present invention are not limited to the aforementioned object, but other objects not described herein will be clearly understood by those skilled in the art from the following description.

To solve the above-described objects, the present invention provides a photoresist composition characterized by including a photosensitive polymer, a photoacid generator (PAG), and a solvent, wherein the photosensitive polymer contains a sulfonate group bonded with an α-trifluoromethylbenzyl group.

To solve the above-described objects, the present invention provides a photoresist composition characterized by including a photosensitive polymer, a photoacid generator (PAG), and a solvent, wherein the photosensitive polymer contains a first repeating unit according to Formula 1-1, a second repeating unit according to Formula 2-1, or a third repeating unit according to Formula 3-1.

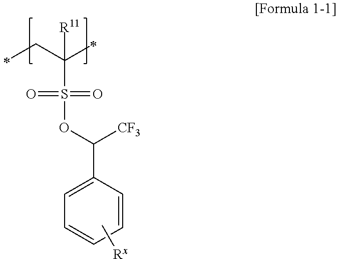

In Formula 1-1, R¹¹ is a hydrogen atom or a methyl group; R^{x} is selected from the group consisting of hydrogen, a methyl group, an isopropyl group (iPr), a tert-butyl (tBu) group, an ethyl group, a phenyl group (Ph), chlorine (Cl), bromine (Br), iodine (I), and a methoxy group; and * is a binding site (e.g., a connection position such as a binding site to another portion (e.g., unit) of the photosensitive polymer).

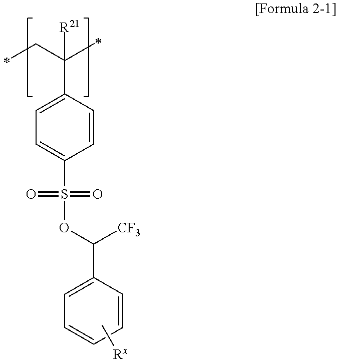

In Formula 2-1, R²¹ is a hydrogen atom or a methyl group; R^{x} is selected from the group consisting of hydrogen, a methyl group, an isopropyl group (iPr), a tert-butyl (tBu) group, an ethyl group, a phenyl group (Ph), chlorine (Cl), bromine (Br), iodine (I) and a methoxy group; and * is a binding site.

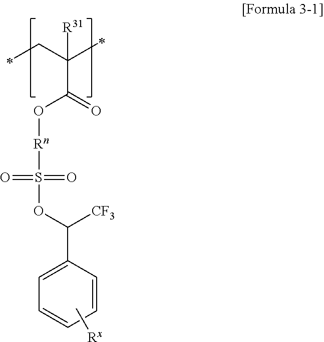

In Formula 3-1, R³¹ is a hydrogen atom or a methyl group, Rⁿ is an alkyl group having n carbons (n is a natural number of 1 to 30) (e.g., a C1-C30 alkyl group); R^{x} is selected from the group consisting of hydrogen, a methyl group, an isopropyl group (iPr), tert-butyl (tBu) group, an ethyl group, a phenyl group (Ph), chlorine (Cl), bromine (Br), iodine (I), and a methoxy group; * is a binding site.

To solve the above-described objects, the present invention provides methods of manufacturing an integrated circuit device comprising: forming a photoresist film on a lower film using a photoresist composition including a photoacid generator (PAG), a solvent, and a photosensitive polymer that comprises a sulfonate group (—SO₂O—) bonded to an α-trifluoromethylbenzyl group; generating a plurality of acids from the PAG in a first region by exposing the first region, which is a portion of the photoresist film, to provide an exposed first region and inducing a polarity change of the photosensitive polymer through a deprotection reaction of the α-trifluoromethylbenzyl group using the plurality of acids; forming a photoresist pattern with a non-exposed region of the photoresist film by removing the exposed first region from the photoresist film using a developing solution; and processing the lower film using the photoresist pattern.

### BRIEF DESCRIPTION OF THE DRAWINGS

Embodiments of the inventive concepts will be more clearly understood from the following detailed description taken in conjunction with the accompanying drawings in which:

FIG. 1 is a flowchart for a method of manufacturing an integrated circuit device according to some embodiments; and

FIG. 2A to FIG. 2E are cross-sectional views illustrating aspects of a method of manufacturing an integrated circuit device according to some embodiments.

### DETAILED DESCRIPTION OF THE EMBODIMENTS

Hereinafter, the present invention will be explained in detail with reference to the accompanying drawings. Like drawing reference numerals are used for like elements, and duplicate descriptions thereof will be omitted.

In the present specification, when a chemical bond is not drawn at a position where a chemical bond should be drawn in a formula, it may mean that a hydrogen atom is bonded at the position, unless otherwise defined.

A photoresist composition according to some embodiments may include a photosensitive polymer, a photoacid generator (PAG), and a solvent. The photosensitive polymer may include a sulfonate group (—SO₂O—).

In some embodiments, the photosensitive polymer may include a first repeating unit according to Formula 1.

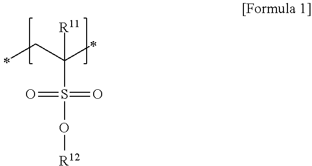

In Formula 1, R¹¹ is a hydrogen atom or a methyl group; R¹² is an acid labile protecting group; and * is a binding site.

In some embodiments, the acid labile protecting group, R¹², may be selected from a substituted or unsubstituted t-butyl group, and a substituted or unsubstituted tertiary alicyclic group having 3 to 30 carbons.

The term “substituted” as used herein is intended to mean including at least one substituent, for example, a halogen atom (e.g., a fluorine (F) atom, a chlorine (Cl) atom, bromine (Br) atom, or an iodine (I) atom), hydroxyl, amino, thiol, carboxyl, carboxylate, ester, amide, nitrile, sulfide, disulfide, nitro, an alkyl group having 2 to 20 carbons (i.e., a C2-C20 alkyl), a cycloalkyl group having 1 to 20 carbons, an alkenyl group having 2 to 20 carbons, an alkoxy group having 1 to 20 carbons, an alkenoxy group having 2 to 20 carbons, an aryl group having 6 to 30 carbons, an aryloxy group having 6 to 30 carbons, an alkylaryl group having 7 to 30 carbons, or an alkyl aryloxy group having 7 to 30 carbons.

In some embodiments, the acid labile protecting group, R¹², may have an unsubstituted structure. For example, the acid labile protecting group may comprise an unsubstituted t-butyl group or an unsubstituted tertiary alicyclic group having 3 to 30 carbons (i.e., an unsubstituted C3-C30 tertiary alicyclic group).

In some embodiments, the acid labile protecting group, R¹², may have a structure substituted with a first substituent. For example, the acid labile protecting group comprise a t-butyl group substituted with the first substituent, or a C3-C30 tertiary alicyclic group substituted with the first substituent. The first substituent may be formed of an alkyl group having 1 to 10 carbons, an alkoxy group having 1 to 10 carbons, a halogen atom, a halogenated alkyl group having 1 to 10 carbons, a hydroxyl group, an unsubstituted aryl group having 6 to 30 carbons, or an aryl group having 6 to 30 carbons, in which some carbon atoms constituting the first substituent are substituted with a group containing a halogen atom or a hetero atom. The halogen atom that may be contained in the first substituent may be selected from a fluorine (F) atom, a chlorine (Cl) atom, a bromine (Br) atom, and an iodine (I) atom. The halogenated alkyl group may contain at least one halogen atom selected from a fluorine (F) atom, a chlorine (Cl) atom, a bromine (Br) atom, and an iodine (I) atom. The hetero atom may be an oxygen atom, a sulfur atom, or a nitrogen atom. For example, the heteroatom-containing group may be —O—, —C(═O)—O—, —O—C(═O)—, —C(═O)—, —O—C(═O)—O—, —C(═O)—NH—, —NH—, —S—, —S(═O)2-, or —S(═O)2-O—.

In some embodiments, the acid labile protecting group (e.g., acid-decomposable protecting group), R¹², may be a linear-chain, branched, or cyclic alkyl group having 1 to 6 carbons, a vinyloxy ethyl group, a tetrahydropyranyl group, a tetrafuranyl group, a trialkylsilyl group, isobornyl, 2-methyl-2-adamantyl, 2-ethyl-2-adamantyl, 3-tetrahydrofuranyl (3-tetrahydrofuranyl), 3-oxocyclohexyl, γ-butyllactone-3-yl, mevalonic lactone, γ-butyrolactone-2-yl (γ-butyrolactone-2-yl), 3-methyl-γ-butyrolactone-3-yl (3-methyl-γ-butyrolactone-3-yl), 2-tetrahydropyranyl (2-tetrahydropyranyl), 2-tetrahydrofuranyl (2-tetrahydrofuranyl), 2,3-propylenecarbonate-1-yl (2,3-propylenecarbonate-1-yl), 1-methoxyethyl, 1-ethoxyethyl (1-ethoxyethyl), 1-(2-methoxyethoxy)ethyl (1-(2-methoxyethoxy)ethyl), 1-(2-acetoxyethoxy)ethyl (1-(2-acetoxyethoxy)ethyl), t-butoxycarbonylmethyl, methoxymethyl, ethoxymethyl, trimethoxysilyl, triethoxysilyl, a methoxyethyl group, an ethoxyethyl group, n-propoxyethyl group, an isopropoxyethyl group, a n-butoxyethyl group, an isobutoxyethyl group, a tert-butoxyethyl group, a cyclohexyloxy ethyl group, a methoxypropyl group, an ethoxypropyl group, a 1-methoxy-1-methyl-ethyl group, a 1-ethoxy-1-methylethyl group, tert-butoxycarbonyl (t-BOC), or a tert-butoxycarbonylmethyl group. Examples of a linear-chain, or branched alkyl group may include a methyl group, an ethyl group, a propyl group, an isopropyl group, a n-butyl group, an isobutyl group, a tert-butyl group, a pentyl group, an isopentyl group, a neopentyl group, and the like, but are not limited thereto. In addition, examples of a cyclic alkyl group may include a cyclopentyl group or a cyclohexyl group, but are not limited thereto.

In some embodiments, the photosensitive polymer may include a sulfonate group (—SO₂O—) bonded with an α-trifluoromethylbenzyl group. That is, in some embodiments, the photosensitive polymer may include an α-trifluoromethylbenzyl group as an acid labile protecting group. In some embodiments, the photosensitive polymer may include a first repeating unit according to Formula 1-1.

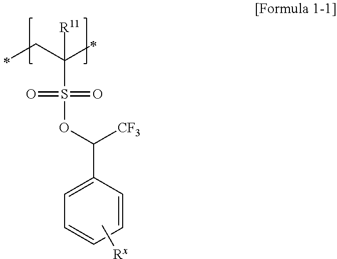

In Formula 1-1, R¹¹ is a hydrogen atom or a methyl group; R^{x} may be selected from the group consisting of hydrogen, a methyl group, an isopropyl group (iPr), a tert-butyl (tBu) group, an ethyl group, a phenyl group (Ph), chlorine (Cl), bromine (Br), iodine (I) and a methoxy group, but is not limited thereto; and * is a binding site.

In some embodiments, R^{x} bonded to the α-trifluoromethylbenzyl group may be, as shown in the following structure, a structure in which R^{x} is bonded at an ortho position with respect to the position of the trifluoromethyl of the benzene ring.

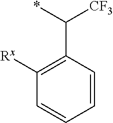

In some embodiments, R^{x} bonded to the α-trifluoromethylbenzyl may be, as shown in the following structure, a structure in which R^{x} is bonded at a meta position with respect to the position of the trifluoromethyl of the benzene ring.

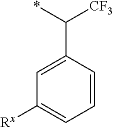

In some embodiments, R^{x} bonded to the α-trifluoromethylbenzyl group may be, as shown in the following structure, a structure in which R^{x} is bonded at a para position with respect to the position of the trifluoromethyl of the benzene ring.

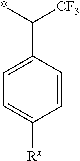

In some embodiments, the photosensitive polymer may include a second repeating unit according to Formula 2.

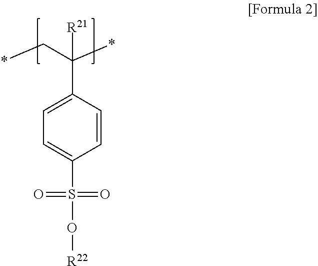

In Formula 2, R²¹ is a hydrogen atom or a methyl group; R²² is an acid labile protecting group; Rⁿ is an alkyl group having n (n is a natural number of 1 to 30) carbons (e.g., a C1-C30 alkyl); and * is a binding site.

In some embodiments, the acid labile protecting group, R²², may be selected from a substituted or unsubstituted t-butyl group and a substituted or unsubstituted tertiary alicyclic group having 3 to 30 carbons. In some embodiments, the acid labile protecting group, R²², is an acid labile protecting group as described for the acid labile protecting group R¹² of Formula 1.

In some embodiments, the photosensitive polymer may contain a sulfonate group (—SO₂O—) bonded to the α-trifluoromethylbenzyl group. That is, the photosensitive polymer may include an α-trifluoromethylbenzyl group as an acid labile protecting group. In some embodiments, the photosensitive polymer may include a second repeating unit according to Formula 2-1.

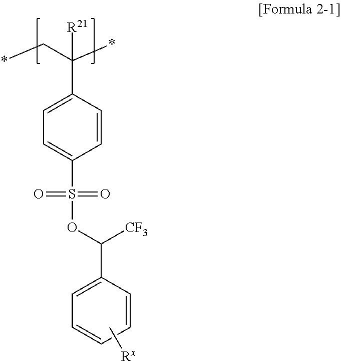

In Formula 2-1, R²¹ is a hydrogen atom or a methyl group; R^{x} may be selected from the group consisting of hydrogen, a methyl group, an isopropyl group (iPr), a tert-butyl (tBu) group, an ethyl group, a phenyl group (Ph), chlorine (Cl), bromine (Br), iodine (I) and a methoxy group, but is not limited thereto; and * is a binding site.

In some embodiments, R^{x} is bonded to the α-trifluoromethylbenzyl group, as described above, and may be a structure in which R^{x} is bonded at the ortho, meta, or para position with respect to the position of the trifluoromethyl of benzene ring.

In some embodiments, the photosensitive polymer may include a third repeating unit according to Formula 3.

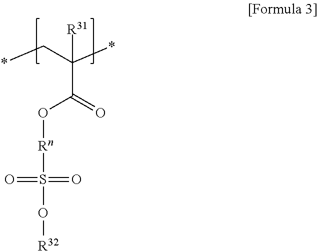

In Formula 3, R³¹ is a hydrogen atom or a methyl group; R³² is an acid labile protecting group; and * is a binding site.

In some embodiments, the acid labile protecting group, R³², may be selected from a substituted or unsubstituted t-butyl group and a substituted or unsubstituted tertiary alicyclic group having 3 to 30 carbons. In some embodiments, the acid labile protecting group, R³², is an acid labile protecting as described for the acid labile protecting group R¹² of Formula 1.

In some embodiments, the photosensitive polymer may contain sulfonate group (—SO₂O—) bonded to the α-trifluoromethylbenzyl group. That is, the photosensitive polymer may include an α-trifluoromethylbenzyl group as an acid labile protecting group. In some embodiments, the photosensitive polymer may include a third repeating unit according to Formula 3-1.

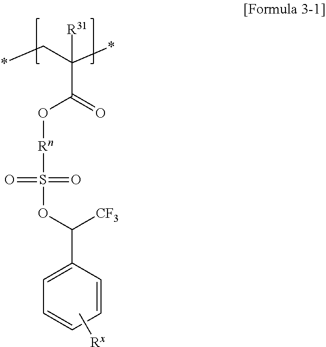

In Formula 3-1, R³¹ is a hydrogen atom or a methyl group; Rⁿ is selected from the group consisting of an alkyl group having n (n is a natural number of 1 to 30) carbons (e.g., a C1-C30 alkyl); R^{x} is selected from hydrogen, a methyl group, an isopropyl group (iPr), a tert-butyl (tBu) group, an ethyl group, a phenyl group, chlorine (Cl), bromine (Br), iodine (I), and a methoxy group, but is not limited thereto; and * is a binding site.

In some embodiments, R^{x} bonded to the α-trifluoromethylbenzyl group, as described above, may be a structure in which R^{x} is bonded at the ortho, meta, or para position with respect to the position of the trifluoromethyl of the benzene ring.

In some embodiments, the photosensitive polymer may include a first repeating unit, a second repeating unit, or a third repeating unit. That is, the photosensitive polymer may include at least one among the first repeating unit, second repeating unit, and third repeating unit.

In some embodiments, the photosensitive polymer may include a structure such as Structural Formula 1, in which the first repeating unit and the second repeating unit are bonded to each other; Structural Formula 2, in which the first repeating unit and the third repeating unit are bonded to each other; Structural Formula 3, in which the second repeating unit and the third repeating unit are bonded to each other; and/or Structural Formula 4, in which the first repeating unit, the second repeating unit, and the third repeating unit are bonded to each other.

The photosensitive polymer is not limited to a structure such as Structural Formula 1, Structural Formula 2, Structural Formula 3, or Structural Formula 4. In some embodiments, the photosensitive polymer may include various other structures comprising at least one first repeating unit, second repeating unit, and third repeating unit as a repeating structure. In some embodiments, the first repeating unit, the second repeating unit, and the third repeating unit are not necessarily bonded in numerical order of the first repeating unit, the second repeating unit, and the third repeating unit. Thus, for example, the repeating units may be bonded in various orders, such as in an order of a first repeating unit, a third repeating unit, and a second repeating unit; or any variation thereof.

In some embodiments, the photosensitive polymer comprises a structure according to Structural Formula 1.

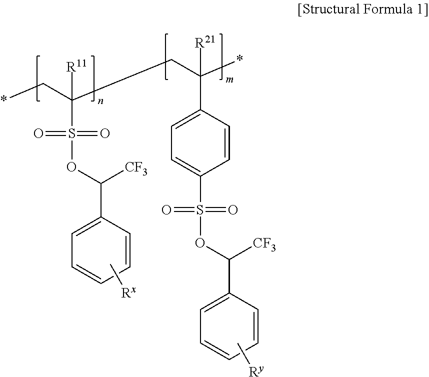

In Structural Formula 1, R¹¹ and R²¹ may each independently be a hydrogen atom or a methyl group; R^{x} and R^{y} may each independently be selected from hydrogen, a methyl group, an isopropyl group (iPr), a tert-butyl (tBu) group, an ethyl group, a phenyl group (Ph), chlorine (Cl), bromine (Br), iodine (I) and a methoxy group, but is not limited thereto; * is a binding site; and n/(n+m) is 0.2 to 0.8. In some embodiments, n and m are in a range of 0 to 500. In some embodiments, n and m are in a range of 300 to 1000.

In some embodiments, the photosensitive polymer comprises a structure according to Structural Formula 2.

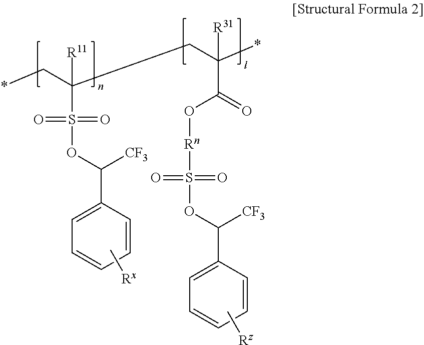

In Structural Formula 2, R¹¹ and R³¹ may each independently be a hydrogen atom or a methyl group; R^{x} and R^{z} may each independently be selected from hydrogen, a methyl group, an isopropyl group (iPr), a tert-butyl (tBu) group, an ethyl group, a phenyl group (Ph), chlorine (Cl), bromine (Br), iodine (I) and a methoxy group, but is not limited thereto;
Rⁿ is an alkyl group having n (n is a natural number of 1 to 30) carbons (e.g., a C1-C30 alkyl); * is a binding site;
   and n/(n+l) is 0.2 to 0.8. In some embodiments, n and l are in a range of 0 to 500. In some embodiments, n and l are in a range of 300 to 1000.

In some embodiments, the photosensitive polymer comprises a structure according to Structural Formula 3.

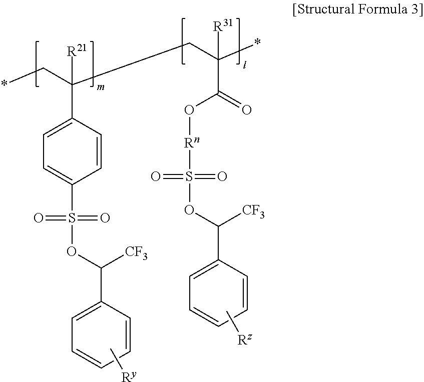

In Structural Formula 3, R²¹ and R³¹ may each independently be a hydrogen atom or a methyl group; R^{y} and R^{z} may each independently be selected from hydrogen, a methyl group, an isopropyl group (iPr), a tert-butyl (tBu) group, an ethyl group, a phenyl group (Ph), chlorine (Cl), bromine (Br), iodine (I) and a methoxy group, but is not limited thereto;
Rⁿ is an alkyl group having n (n is a natural number of 1 to 30) carbons (e.g., a C1-C30 alkyl);
* is a binding site; and
m/(m+l) is 0.2 to 0.8. In some embodiments, m and l are in a range of 0 to 500. In some embodiments, m and l are in a range of 300 to 1000.

In some embodiments, the photosensitive polymer comprises a structure according to Structural Formula 4.

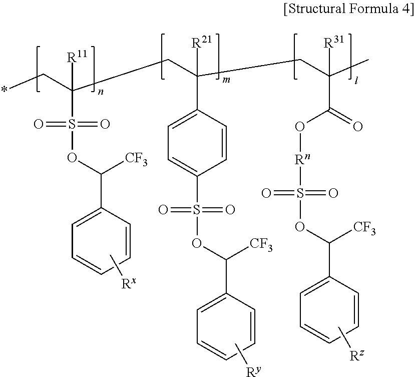

In Structural Formula 4, R¹¹, R²¹, and R³¹ may each independently be a hydrogen atom or a methyl group; R^{x}, R^{y}, and R^{z} may each independently be selected from hydrogen, a methyl group, an isopropyl group (iPr), a tert-butyl (tBu) group, an ethyl group, a phenyl group (Ph), chlorine (Cl), bromine (Br), iodine (I) and a methoxy group, but is not limited thereto;
Rⁿ is an alkyl group having n (n is a natural number of 1 to 30) carbons (e.g., a C1-C30 alkyl); and
n/(n+m+l) and m(n+m+l) are each independently 0.05 to 0.45. In some embodiments, n, m and l are in a range of 0 to 500. In some embodiments, n, m and 1 are in a range of 300 to 1000.

In some embodiments, the photosensitive polymer may be formed of only a first polymer having only one of the first repeating unit, the second repeating unit, and the third repeating unit as described herein.

In some embodiments, the photosensitive polymer may be formed of a blend of a first polymer having only one of the first repeating unit, the second repeating unit, and the third repeating unit; and a second polymer having two or more of the first repeating unit, the second repeating unit, and the third repeating unit.

In some embodiments, the third repeating unit may include a structure obtained from hydroxystyrene or a hydroxystyrene derivative. In some embodiments, the hydroxystyrene derivative may include a hydroxystyrene in which a hydrogen atom at an α-position is substituted with a C1-C5 alkyl group or a C1-C5 halogenated alkyl group.

In some embodiments, the photosensitive polymer may further include a fourth repeating unit. In some embodiments, the fourth repeating unit may include a structure obtained from a methoxystyrene. In some embodiments, the fourth repeating unit may include a structure of Formula 4.

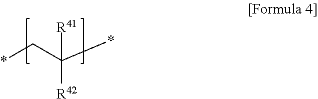

In Formula 4, R⁴¹ is a hydrogen atom or a methyl group; R⁴² is a C6-C30 aryl group containing at least one hydroxy group or at least one methoxy group; and * is a binding site.

In some embodiments, R⁴¹ is a hydrogen atom or a methyl group; and R⁴² is selected from a phenyl group, a naphthyl group, and an anthracenyl group, wherein R⁴² comprises at least one hydroxy group or at least one methoxy group.

In some embodiments, R⁴² may be selected from the following structures, but is not limited thereto. In the following structures, “*” is a binding site.

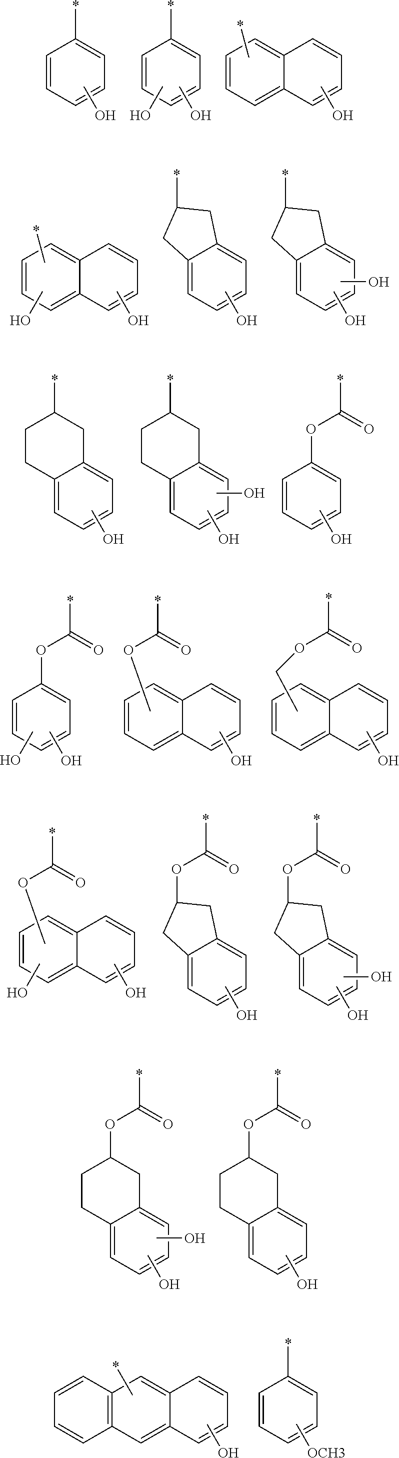

In some embodiments, a phenolic acid or a corresponding Brønsted acid may be generated by being decomposed due to an action of another acid.

In some embodiments, the photosensitive polymer may include a structure in which at least one among the first repeating unit, the second repeating unit, and the third repeating unit is bonded to the fourth repeating unit. For example, the photosensitive polymer may include a structure such as Structural Formula 5, in which the first repeating unit and the fourth repeating unit are bonded to each other; Structural Formula 6, in which the second repeating unit and the fourth repeating unit are bonded to each other; and/or Structural Formula 7, in which the third repeating unit and the fourth repeating unit are bonded to each other.

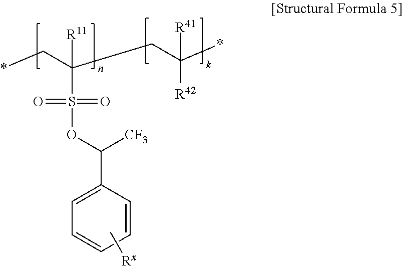

In Structural Formula 5, R¹¹ is a hydrogen atom or a methyl group; R^{x} may be selected from the group consisting of hydrogen, a methyl group, an isopropyl group (iPr), a tert-butyl (tBu) group, an ethyl group, a phenyl group (Ph), chlorine (Cl), bromine (Br), iodine (I) and a methoxy group, but is not limited thereto; R⁴¹ is a hydrogen atom or a methyl group;

R⁴² is a C6-C30 aryl group containing at least one hydroxy group or at least one methoxy group; * is a binding site; and n/(n+k) is 0.2 to 0.8. In some embodiments, n and k are in a range of 0 to 500. In some embodiments, n and k are in a range of 300 to 1000.

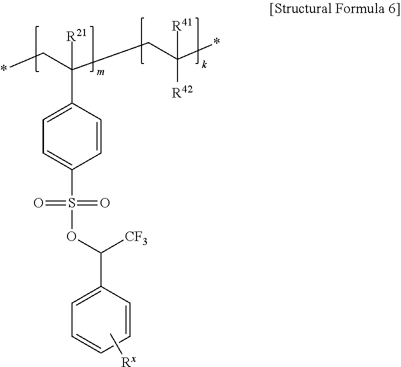

In Structural Formula 6, R²¹ is a hydrogen atom or a methyl group; R^{x} may be selected from the group consisting of hydrogen, a methyl group, an isopropyl group (iPr), a tert-butyl (tBu) group, an ethyl group, a phenyl group (Ph), chlorine (Cl), bromine (Br), iodine (I) and a methoxy group, but is not limited thereto; R⁴¹ is a hydrogen atom or a methyl group;
R⁴² is a C6-C30 aryl group containing at least one hydroxy group or at least one methoxy group; * is a binding site; and m/(m+k) is 0.2 to 0.8. In some embodiments, m and k are in a range of 0 to 500. In some embodiments, m and k are in a range of 300 to 1000.

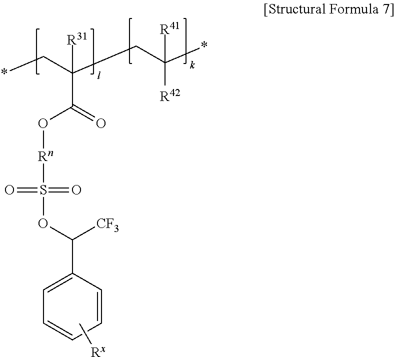

In Structural Formula 7, R³¹ is a hydrogen atom or a methyl group; R^{x} may be selected from the group consisting of hydrogen, a methyl group, an isopropyl group (iPr), a tert-butyl (tBu) group, an ethyl group, a phenyl group (Ph), chlorine (Cl), bromine (Br), iodine (I) and a methoxy group, but is not limited thereto; R⁴¹ is a hydrogen atom or a methyl group;
R⁴² is a C6-C30 aryl group containing at least one hydroxy group or at least one methoxy group; * is a binding site; and l/(l+k) is 0.2 to 0.8. In some embodiments, l and k are in a range of 0 to 500. In some embodiments, l and k are in a range of 300 to 1000.

In some embodiments, the photosensitive polymer may further include a fifth repeating unit formed of materials that generate one or more acids when exposed to a light source such as, but not limited to, a KrF excimer laser (248 nm), an ArF excimer laser (193 nm), a F2 excimer layer (157 nm), and/or a EUV laser (13.5 nm). In some embodiments, the photosensitive polymer may include a PAG as a repeating unit. In some embodiments, the photosensitive polymer may include a photodegradable base (e.g., a photo-decomposable base) as a repeating unit.

In some embodiments, the photosensitive polymer may further include at least one repeating unit among a sixth repeating unit comprising a (meth)arylate-based monomer unit comprising a substituent containing a hydroxy group (—OH), and a seventh repeating unit comprising a (meth)acrylate-based monomer unit having a substituent substituted with fluorine.

In the photoresist composition, according to some embodiments, the PAG may generate one or more acids when exposed to a light source selected from a KrF excimer laser (248 nm), an ArF excimer laser (193 nm), a F2 excimer layer (157 nm), and a EUV laser (13.5 nm). The PAG may be formed of materials that generate, due to exposure (e.g., upon exposure to light), a relatively strong acid having an acid dissociation constant (pKa) of about −20 to about 1. The PAG may be an independent ionic PAG, which is additionally comprised within the photoresist composition. In some embodiments, when the photosensitive polymer includes the fifth repeating unit formed of materials generating acids when exposed to a light or is formed of photodegradable bases, the PAG may further be added into the photoresist composition, and an amount thereof may be adjusted as needed, which may aid in providing sufficient sensitivity.

In some embodiments, the PAG may be formed of and/or may comprise a triarylsulfonium salt, diaryliodonium salt, sulfonate, or any mixture thereof. For example, the PAG may be formed of triphenylsulfonium triflate, triphenylsulfonium antimonate, diphenyliodonium triflate, diphenyliodonium antimonate, methoxy diphenyl iodonium triflate, di-t-butyl diphenyliodonium triflate, 2,6-dinitrobenzyl group sulfonates, pyrogallol tris(alkyl sulfonates), N-hydroxysuccinimide triflate, norbornene-dicarboximide-triflate, triphenylsulfonium nonaflate, diphenyliodonium nonaflate, methoxy diphenyl iodonium nonaflate, di-t-butyl diphenyliodonium nonaflate, N-hydroxysuccinimide nonaflate, norbornene-dicarboximide-nonaflate, triphenylsulfonium perfluorobutanesulfonate, triphenylsulfonium perfluorooctanesulfonate (PFOS), diphenyliodonium PFOS, methoxy diphenyliodonium PFOS, di-t-butyl diphenyliodonium triflate, N-hydroxysuccinimide PFOS, norbornene-dicarboximide PFOS, or any mixture thereof.

In the photoresist composition, according to some embodiments, the PAG may be included in an amount of about 0.1 wt % to about 5 wt % with respect to the total weight of the photosensitive polymer, but is not limited thereto. In some embodiments, the photoresist composition comprises a PAG in an amount of about 0.1% to about 5% by weight of the photosensitive polymer.

In some embodiments, the photoresist composition may further include a basic quencher.

The basic quencher may comprise compounds that may trap one or more acids in a non-exposed region of a photoresist film (e.g., the region of the photoresist film that is not exposed to light) when the one or more acids, which are generated from the PAG contained in the photoresist composition, are diffused into the non-exposed region of the photoresist film (e.g., the region of the photoresist film that is not exposed to any light). By containing the basic quencher in the photoresist composition according to some embodiments, the diffusion rate of the one or more acids may be suppressed.

In some embodiments, the basic quencher may be formed of and/or may comprise a primary aliphatic amine, secondary aliphatic amine, tertiary aliphatic amine, aromatic amine, heterocyclic ring-containing amine, a nitrogen-containing compound having a carboxyl group, a nitrogen-containing compound having a sulfonyl group, a nitrogen-containing compound having a hydroxyl group, a nitrogen-containing compound having a hydroxyphenyl group, an alcoholic nitrogen-containing compound, amides, imides, carbamates, or ammonium salts. For example, the basic quencher may include triethanolamine, triethyl amine, tributyl amine, tripropyl amine, hexamethyl disilazane, aniline, N-methylaniline, N-ethylaniline, N-propylaniline, N,N-dimethylaniline, N,N-bis(hydroxyethyl)aniline, 2-methylaniline, 3-methylaniline, 4-methylaniline, ethylaniline, propylaniline, dimethylaniline, 2,6-diisopropylaniline, trimethylaniline, 2-nitroaniline, 3-nitroaniline, 4-nitroaniline, 2,4-dinitroaniline, 2,6-dinitroaniline, 3,5-dinitroaniline, N,N-dimethyl toluidine, or any combination thereof, but is not limited the above examples.

In some embodiments, the basic quencher may be made of and/or may comprise a photodegradable base. The photodegradable base may be made of and/or may comprise compounds that serve to generate one or more acids due to exposure (e.g., exposure to light) and neutralize one or more acids before exposure (e.g., exposure to light). When the photodegradable base is decomposed by exposure (e.g., exposure to light), its function to trap the one or more acids may be lost. In some embodiments, when some regions (e.g., a partial region) of the photoresist film, which is formed from a chemical amplification type photoresist composition including the basic quencher formed of the photodegradable base, are exposed (e.g., exposed to light), the photodegradable base loses alkalinity in the exposed region of the photoresist film (e.g., the region of the photoresist film that is exposed to light). Thus, the photodegradable base may trap one or more acids in the non-exposed region of the photoresist film (e.g., the region of the photoresist film that is not exposed to any light). In some embodiments, the photoresist composition including a basic quencher can suppress diffusion of the one or more acids from the exposed region to the non-exposed region.

The photodegradable base may include a carboxylate or a sulfonate of a photodegradable cation. For example, the photodegradable cation may form a complex with an anion of a carboxylic acid. The carboxylic acid may be, for example, a formic acid, an acetic acid, a propionic acid, a tartaric acid, a succinic acid, a cyclohexyl carboxylic acid, a benzoic acid, or a salicylic acid, but is not limited thereto.

In the photoresist composition according to some embodiments, the basic quencher may be included in an amount of about 0.01 wt % to about 5.0 wt % with respect to the total weight of the photosensitive polymer, but is not limited thereto. In some embodiments, the photosensitive polymer comprises a basic quencher in an amount of about 0.1% to about 5% by weight of the photosensitive polymer.

In the photoresist composition, according to some embodiments, the solvent may be an organic solvent. In embodiments, the solvent may include at least one ether, alcohol, glycol ether, an aromatic hydrocarbon compound, ketone, and/or ester. For example, the solvent may be selected from ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol mono, methyl ether acetate, propylene glycol monoethyl ether, propylene glycol monoethyl ether acetate, propylene glycol propyl ether acetate, propylene glycol monobutyl ether, propylene glycol monobutyl ether acetate, toluene, xylene, methyl ethyl ketone, cyclopentanone, cyclopentanone hexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, and butyl lactate, etc. These examples may be used alone or in a combination of two or more, as a solvent. In some embodiments, an amount of the solvent within the photoresist composition may be adjusted such that a solid content within the photoresist composition is about 3 wt % to about 20 wt %. In some embodiments, the photoresist composition comprises a solvent such that a solid content within said photoresist composition is present in an amount of about 3% to about 20% by weight of the photoresist composition.

In some embodiments, the photoresist composition may further include a surfactant, a dispersant, a desiccant, and/or a coupling agent.

The surfactant may serve to improve a coating uniformity and wettability of the photoresist composition. In some embodiments, the surfactant may be selected from fluoroalkyl benzene sulfonate, fluoroalkyl carboxylate, fluoroalkyl polyoxyethylene ether, fluoroalkyl ammonium iodide, fluoroalkyl betaine, fluoroalkyl sulfonate, diglycerin tetrakis, fluoroalkyl poly oxyethylene ether, fluoroalkyl trimethyl ammonium salt, fluoroalkyl amino sulfonate, polyoxyethylene nonyl phenyl ether, polyoxyethylene octyl phenyl ether, polyoxyethylene alkyl ether, polyoxyethylene lauryl ether, polyoxyethylene oleyl ether, polyoxyethylene tridecyl ether, polyoxyethylene cetyl ether, polyoxyethylene stearyl ether, polyoxyethylene laurate, polyoxyethylene oleate, polyoxyethylene stearate, polyoxyethylene laurylamine, sorbitan laurate. sorbitan palmitate, sorbitan stearate, sorbitan oleate, sorbitan fatty acid ester, polyoxyethylene sorbitan laurate, polyoxyethylene sorbitan palmitate, polyoxyethylene sorbitan stearate, polyoxyethylene sorbitan, sorbitan oleate, polyoxyethylene naphthyl ether, alkylbenzene sulfonate, and alkyl diphenyl ether disulfonate, but is not limited thereto. The surfactant may be included in an amount of about 0.001 wt % to about 3 wt % with respect to the total weight of the photoresist composition, but is not limited thereto. In some embodiments, the photoresist composition comprises a surfactant in an amount of about 0.001% to about 3% by weight of the photoresist composition.

The dispersant may serve to ensure that each component comprising the photoresist composition is uniformly dispersed within the photoresist composition. In some embodiments, the dispersant may be formed of an epoxy resin, polyvinyl alcohol, polyvinyl butyral, polyvinylpyrrolidone, glucose, sodium dodecyl sulfate, sodium citrate, oleic acid, linoleic acid, or any combination thereof, but is not limited thereto. If the photoresist composition includes the dispersant, the dispersant is included in an amount of about 0.001 wt % to about 5 wt % with respect to the total weight of the photoresist composition. In some embodiments, the photoresist composition comprises a dispersant in an amount of about 0.001% to about 5% by weight of the photoresist composition.

The desiccant may serve to prevent an adverse effect due to moisture in the photoresist composition. For example, the desiccant may prevent a metal contained in the photoresist composition from being oxidized due to moisture. In embodiments, the desiccant may be formed of polyoxyethylene nonylphenol ether, polyethylene glycol, polypropylene glycol, polyacrylamide, or a combination thereof, but is not limited thereto. When the photoresist composition includes the desiccant, the desiccant is included in an amount of about 0.001 wt % to about 10 wt % with respect to the total weight of the photoresist composition. In some embodiments, the photoresist composition comprises a desiccant in an amount of about 0.001% to about 10% by weight of the photoresist composition.

The coupling agent may serve to improve adhesion with a lower film when the photoresist composition is applied onto the lower film. In some embodiments, the coupling agent may include a silane coupling agent. The silane coupling agent may be formed of vinyltrimethoxysilane, vinyltriethoxysilane, vinyltrichlorosilane, vinyltris(β-methoxyethoxy)silane, 3-methacryloxypropyltrimethoxysilane, 3-acryloxypropyltrimethoxysilane, p-styryltrimethoxysilane, 3-methacryloxypropylmethyldimethoxysilane, 3-methacryloxypropylmethyldiethoxysilane, or trimethoxy[3-(phenylamino)propyl]silane, but is not limited thereto. When the photoresist composition includes the coupling agent, the coupling agent is included in an amount of about 0.001 wt % to about 5 wt % with respect to the total weight of the photoresist composition. In some embodiments, the photoresist composition comprises a coupling agent in an amount of about 0.001% to about 3% by weight of the photoresist composition.

In the photoresist composition according to some embodiments, when the solvent is formed of only an organic solvent, the photoresist composition may further include water. In some embodiments, water may be present in the photoresist composition in an amount of about 0.001 wt % to about 0.1 wt %. In some embodiments, the photoresist composition comprises water in an amount of about 0.001% to about 0.1% by weight of the photoresist composition.

Hereinafter, a case where the photosensitive polymer contained in the photoresist composition undergoes a deprotection reaction due to a photoacid will be specifically described. In some embodiments, when the photosensitive polymer includes the first repeating unit, the second repeating unit, and/or the third repeating unit, the first repeating unit, the second repeating unit, and/or the third repeating unit may undergo a deprotection reaction due to a photoacid. In this case, through the deprotection reaction, an acid labile protecting group (e.g., R¹² in the first repeating unit, R²² in the second repeating unit, and R³² in the third repeating unit as described above) contained in the first repeating unit, the second repeating unit, and/or the third repeating unit may be released (e.g., the chemical bond between the acid labile protecting group and the first repeating unit, the second repeating unit, and/or the third repeating unit is broken).

In this case, as the acid labile protecting group is released, the sulfonate group (—SO₃—) contained in the first repeating unit, the second repeating unit and/or the third repeating unit is bonded with a photoacid, that is a hydrogen ion (H+), and thus a structure terminated by a sulfonic acid (—SO₂OH) group may be obtained.

For example, a deprotection reaction such as Reaction Scheme 1, shown below, may occur. When the first repeating unit includes an α-trifluoromethylbenzyl group as the acid labile protecting group, as the α-trifluoromethylbenzyl group is released, a sulfonate group (—SO₃—) structure contained in the first repeating unit is bonded with a photoacid, that is a hydrogen ion (H+), and thus a structure terminated by the sulfonic acid group (—SO₂OH) may be obtained.

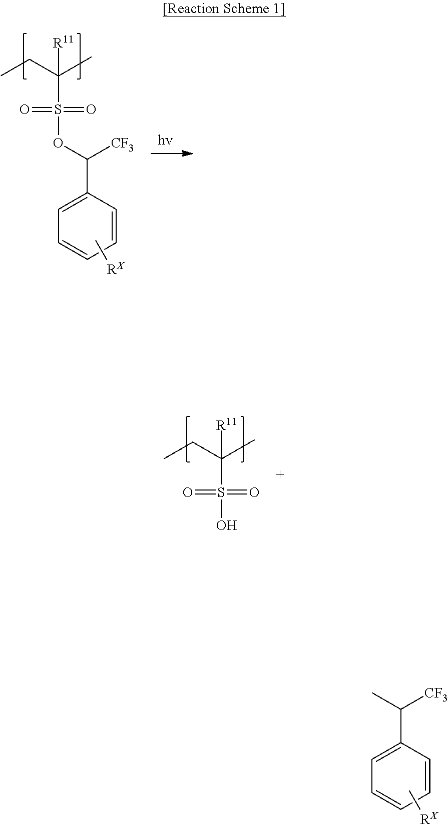

In some embodiments, the second repeating unit and/or the third repeating unit as described herein may undergo a deprotection reaction as shown in Reaction Scheme 1. In some embodiments, when an α-trifluoromethylbenzyl group is the acid labile protecting group, as the α-trifluoromethylbenzyl group is released, a sulfonate group (—SO₃—) structure contained in the second repeating unit and/or the third repeating unit is bonded to the photoacid, that is a hydrogen ion, and thus a structure terminated by a sulfonic acid (—SO₂OH) group may be obtained.

Hereinafter, synthesis examples of the photosensitive polymer contained in the photoresist composition will be specifically described. The synthesis examples described below are merely exemplified to aid in understanding synthesis processes of the photosensitive polymer according to some embodiments of the present invention, and the scope of the present invention is not limited to the following examples.

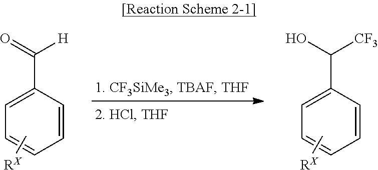

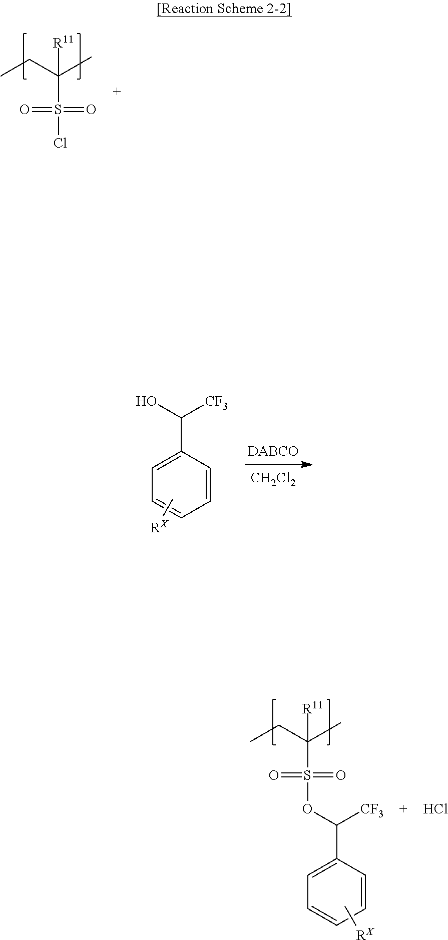

In some embodiments, to synthesize the first repeating unit of Formula 1-1, a synthesis processes of Reaction Scheme 2-1 may be performed. To explain in more detail, 50 mol % of trifluoromethylbenzyl group is bound to R^{x}, and R^{x} may be selected from the group consisting of hydrogen, a methyl group, an isopropyl group (iPr), tert-butyl (tBu) group, an ethyl group, a phenyl group (Ph), chlorine (Cl), bromine (Br), iodine (I), and a methoxy group). This R^{x} bonded trifluoromethylbenzyl group is reacted with 50 mol % of —CF₃SiMe₃, tetrahydrofuran (THF), and tetra-n-butylammonium fluoride (TBAF) for about 1 hour. The reaction products are then reacted with 1 M HCl and THF for about 2 hours to synthesize a preliminary monomer having an acid labile protecting group as previously described.

Then, the synthesis processes of Reaction Scheme 2-2 may be performed. Specifically, the first repeating unit of Formula 1-1 may be synthesized by reacting the preliminary monomer from Reaction Scheme 2-1 with a material in which 50 mol % of SOCl₂ is bound to R¹¹, wherein R¹¹ is a hydrogen atom or a methyl group, using 1.2 eq of triethylenediamine (DABCO, C₆H₁₂N₂) and 0.5 M CH₂Cl₂.

The photoresist composition according to the present invention, compared to a photosensitive polymer containing an ester group (—COO—), has relatively high hydrophobicity since the included photosensitive polymer comprises a sulfonate group (—SO₃—) (C log P: ester group 3.58, a sulfonate group 4.09). Therefore, the solubility of the non-exposed portion in the photoresist film to a developing solution may be lowered (e.g., it does not dissolve in the developing solution). In addition, in the photosensitive polymer containing an ester group (—COO—), as a comparative example, when exposed to light, the ester group (—COO—) is converted to carboxylic acid (—COOH). However, in the photosensitive polymer containing a sulfonate group (—SO₃—), the sulfonate group (—SO₃—) is converted to the sulfonic acid group (—SO₃H) when exposed to light. Thus, the photosensitive polymer containing a sulfonate group (—SO₃—) may have a relatively low ionization constant in comparison to a similar polymer containing an ester group (—COO—) (pKa: carboxyl group about 11 to about 13, sulfonic acid group about 0.2 to about 2). Therefore, the solubility of the exposed portion in the photoresist film, with respect to the developing solution, may be improved.

In some embodiments, the photoresist film obtained from the photoresist composition including the photosensitive polymer of the present invention, provides a dissolution contrast to the developing solution that is maximized between the exposed and non-exposed regions. In some embodiments, the maximized dissolution contrast improves line edge roughness (LER) and/or line width roughness (LWR) of the photoresist film, and thus a high pattern fidelity may be achieved. The photoresist composition including a photosensitive polymer according to the present invention may be advantageous in forming a pattern having a relatively high aspect ratio. For example, the photoresist composition according to the inventive concepts may be advantageous in the photolithography process for forming a pattern having a fine width selected within a range of about 5 nm to about 100 nm.

In some embodiments, a photoresist composition of the present invention having improved dissolution contrast can achieve a narrow pitch of 40 nanometer process (nmP) or less in a pattern formed from a photolithography process.

A method of manufacturing an integrated circuit device using the photoresist composition according to the present invention will be described with reference to specific embodiments.

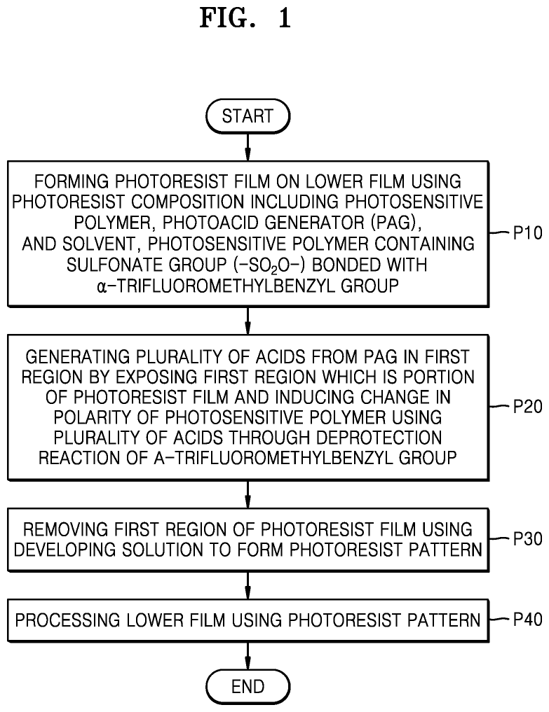

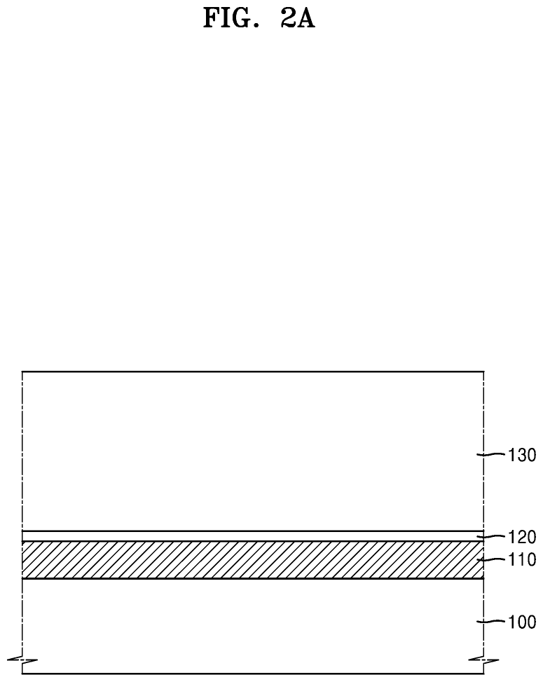

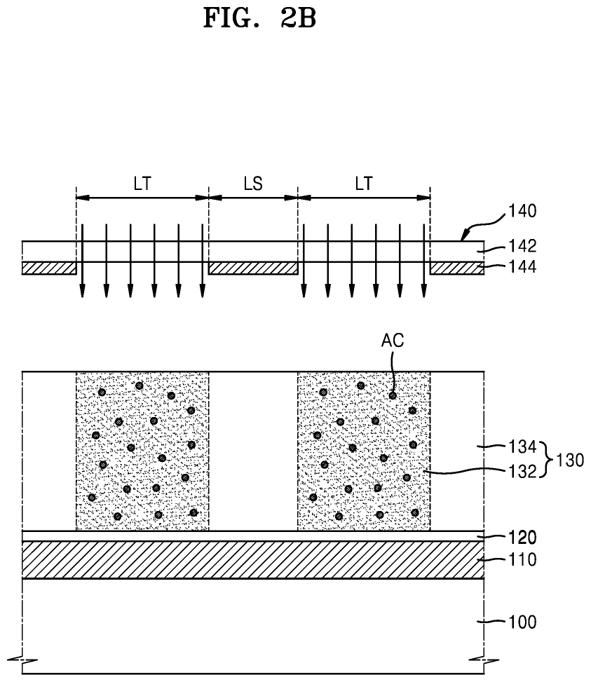

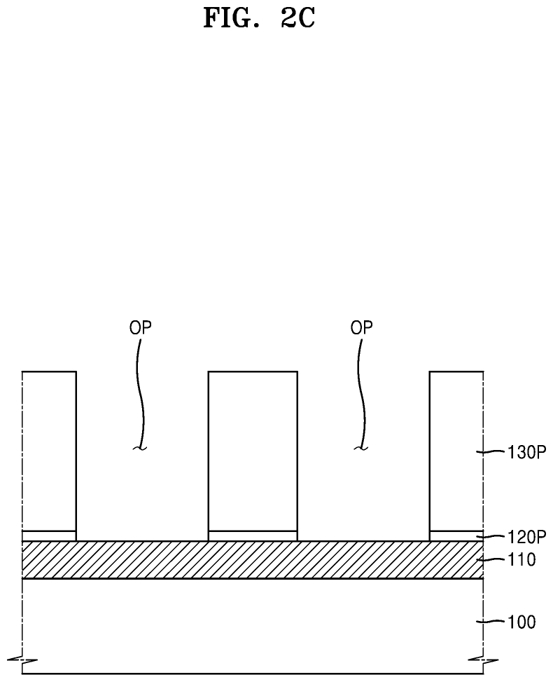

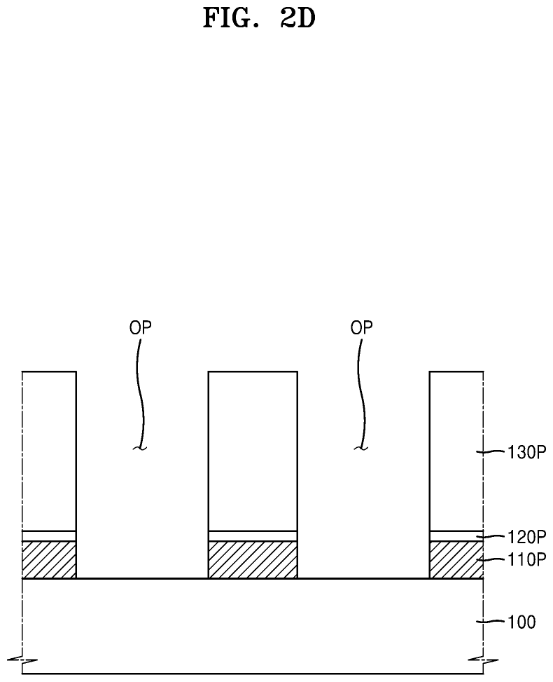

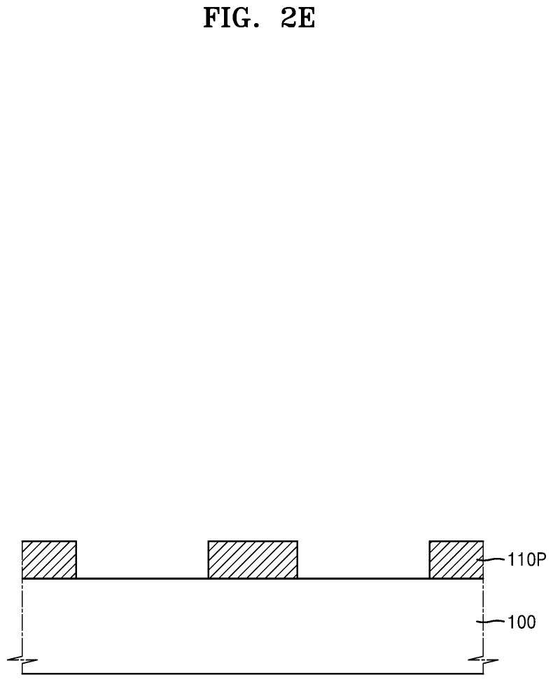

FIG. 1 is a flow chart describing a method of manufacturing an integrated circuit device according to some embodiments. FIG. 2A to FIG. 2E are cross-sectional views illustrating aspects of a photolithography process to explain the method of manufacturing an integrated circuit device according to some embodiments.

Referring to FIG. 1 and FIG. 2A, in the process P10, a photoresist film 130 may be formed on a lower film using the photoresist composition according to the present invention. The lower film may include a substrate 100 and a feature layer 110 formed on the substrate 100. The substrate 100 may include a semiconductor substrate. For example, the substrate 100 may include an element semiconductor material such as Si or Ge, or a compound semiconductor material such as SiGe, SiC, GaAs, InAs, or InP. The feature layer 110 may be an insulating film, a conductive film, or a semiconductor film. For example, the feature layer 110 may be formed of a metal, an alloy, a metal carbide, a metal nitride, a metal oxynitride, a metal oxycarbide, a semiconductor, a polysilicon, an oxide, a nitride, an oxynitride, or any combination thereof, but is not limited thereto.

In some embodiments, as exemplified in FIG. 2A, a developable bottom anti-reflective coating (DBARC) film 120 on the feature layer 110 may be formed before forming the photoresist film 130 on the feature layer 110. In this case, the photoresist film 130 may be formed on a DBARC film 120. The DBARC film 120 may serve to control scattering of light from a light source used during an exposure process for manufacturing an integrated circuit device or to absorb reflected light from the feature layer 110 of a lower part. In some embodiments, the DBARC film 120 may be formed of organic anti-reflective coating (ARC) materials suitable for use with a KrF excimer laser, an ArF excimer laser, or any other light-source. In embodiments, the DVARC film 120 may include an organic ingredient having a light absorption structure. The light absorption structure may be, for example, a hydrocarbon compound having one or more benzene rings or a fused structure of benzene rings. The DBARC film 120 may be formed to a thickness of about 20 nm to about 100 nm, but is not limited thereto. In some embodiments, the DBARC film 120 may be omitted.

For forming the photoresist film 130, the photoresist composition containing the photosensitive polymer according to some embodiments may be used. In some embodiments, the photoresist composition may include a photosensitive polymer containing a sulfonate group (—SO₂O—) bonded to an α-trifluoromethylbenzyl group, a PAG, and a solvent. In some embodiments, the photoresist composition may further include a basic quencher. Specific constitutions of the photosensitive polymer and the photoresist composition are the same as described above.

For forming the photoresist film 130, the photoresist composition according to the present invention may be applied on the DBARC film 120 and then be subjected to a heat treatment. The coating is performed by methods such as a spin coating, a spray coating, and a deep coating. The heat treatment process of the photoresist composition may be performed at about 80° C. to about 300° C. for about 10 seconds to about 100 seconds, but is not limited thereto. The photoresist film 130 may have a thickness of tens of times to hundreds of times the thickness of the DBARC film 120. The photoresist film 130 may be formed to a thickness of about 100 nm to about 6 m, but is not limited thereto.

Referring to FIG. 1 and FIG. 2B, in Process P20, a first region 132, which is a portion of the photoresist film 130, may be exposed (e.g., exposed to light).

In some embodiments, to expose (e.g., expose to light) the first region 132 of the photoresist film 130, a photomask 140 having a plurality of light shielding regions LS and a plurality of light transmitting regions LT may be aligned at a predetermined position on the photoresist film 130, and the first region 132 of the photoresist film 130 may be exposed through the plurality of light transmitting regions LT of the photomask 140. To expose the first region 132 of the photoresist film 130, a KrF excimer laser (248 nm), an ArF excimer laser (193 nm), an F2 excimer laser (157 nm), or an EUV laser (13.5 nm) may be used.

The photomask 140 may include a transparent substrate 142, a plurality of light shielding patterns 144 formed in the plurality of light shielding regions on the transparent substrate 142. The transparent substrate 142 may be formed of quartz. The plurality of light shielding patterns 144 may be formed of chromium (Cr). A plurality of transparent regions LT may be defined by the plurality of light shielding patterns 144. According to the present invention, a reflective-type photomask (not illustrated) for EUV exposure may be used instead of the photomask 140 to expose the first region 132 of the photoresist film 130.

In some embodiments, if the first region 132 of the photoresist film 130 is exposed, one or more acids are generated from the PAG in the first region 132. The first repeating unit, the second repeating unit, and/or the third repeating unit may be deprotected due to the one or more acids generated from the PGA. Thus, an α-trifluoromethylbenzyl group that is contained in the first repeating unit, the second repeating unit and/or the third repeating unit as an acid labile protecting group may be separated from the first repeating unit, the second repeating unit and/or the third repeating unit.

In some embodiments, when the photosensitive polymer further includes a fourth repeating unit having an acid labile protecting group, if the first region 132 of the photoresist film 130 is exposed, one or more acids may be generated from the PGA in the first region 132. Thus, the fourth repeating unit having the acid labile protecting group may be deprotected due to the one or more acids generated from the PAG. Thus, the acid labile protecting group may be separated from the fourth repeating unit.

In some embodiments, when the photosensitive polymer further includes a fifth repeating unit formed of materials generating one or more acids when exposed to any light, or formed of photodegradable bases, if the first region 132 of the photoresist film 130 is exposed to light, one or more acids are generated from the fifth repeating unit in the first region 132, and thus the first repeating unit, the second repeating unit, and the third repeating unit are deprotected due to said one or more acids generated from the fifth repeating unit. Thus, the α-trifluoromethylbenzyl group contained in the first repeating unit, the second repeating unit and/or the third repeating unit as an acid labile protecting group may be separated from the first repeating unit, the second repeating unit, and the third repeating unit.

When the first repeating unit, the second repeating unit and/or the third repeating unit having an acid labile protecting group are deprotected, thereby separating the acid labile protecting group, the sulfonate group included in the photosensitive polymer may be converted to the sulfonic acid group. As a result, the photosensitive polymer may have a polarity (e.g., the photosensitive polymer may become polar). Thus, the first region of the photoresist film 130 may be changed to a state that may make the photosensitive polymer be easily dissolved in the developing solution. For example, when the first repeating unit having an α-trifluoromethylbenzyl group is deprotected and thus the α-trifluoromethylbenzyl group is separated, the reaction in the first repeating unit may be performed as described above with reference to Reaction Scheme 1.

In some embodiments, the second region 134 is a non-exposed region of the photoresist film 130. This second region 134 has a structure in which the photosensitive polymer includes an acid labile protecting group that is relatively hydrophobic compared to the photosensitive polymer of the first region 132. Thus, the photosensitive polymer may be maintained as it is (e.g., it will not dissolve in a developing solution). That is, a structure in which the sulfonate group is bonded to the α-trifluoromethylbenzyl group may be maintained as it is (e.g., it will remain during the development process). Therefore, when the photoresist film 130 is developed during the subsequent processes, solubility of the second region 134 to the developing solution may decrease. Therefore, dissolution contrast between the exposed first region 132 and the non-exposed second region 134 to the developing solution may increase. Therefore, a final pattern having small line edge roughness (LER) and/or line width roughness (LWR) may be obtained on the feature layer 110 during the subsequent processes.

In some embodiments, an annealing process may be performed within the first region 132 of the photoresist film 130 to diffuse a plurality of acids AC. For example, in Process P20 in FIG. 1, after the first region 132 of the photoresist film 130 is exposed, the obtained resultant is annealed at about 50° C. to about 150° C. At least a portion of the plurality of acids AC is diffused in the first region 132, and thus the plurality of acids AC may be relatively uniformly distributed in the first region 132. The annealing may be performed for about 10 seconds to about 100 seconds, but is not limited thereto. For example, the annealing process may be performed at about 100° C. for about 60 seconds.

In other embodiments, no additional annealing process may be performed for diffusing a plurality of acids AC in the first region 132 of the photoresist film 130. In this case, in Process P20 in FIG. 1, the plurality of acids AC may be diffused without the additional annealing process in the first region 132 of the photoresist film 130 while exposing the first region 132 of the photoresist film 130.

In addition, when a basic quencher is included in the photoresist film 130, the basic quencher included in the photoresist film 130 may function as a quenching base that neutralizes the acids unwantedly diffused from the first region 132 into the second region 134, which is a non-exposed region. Therefore, it may be advantageous to maximize dissolution contrast between the first region 132, which is an exposed region, and the second region 134, which is a non-exposed region, to the developing solution.

Referring to FIG. 1 and FIG. 2C, in process P30, the first region 132 of the photoresist film 130 may be removed by developing the photoresist film 130 using a developing solution. As a result, a photoresist pattern 130P is formed by the non-exposed second region 134 of the photoresist film 130P.

The photoresist pattern 130P may include a plurality of openings OP. After forming the photoresist pattern 130P, a DBARC pattern 120P may be formed by removing a portion of the exposed photoresist patterns 130P through the plurality of openings OP in the DBARC film 120.

In some embodiments, an alkaline developing solution may be used for development of the photoresist film 130. The alkaline developing solution may be constituted with 2.38 wt % of tetramethylammonium hydroxide (TMAH) solution.

The deprotection reaction of the first repeating unit, the second repeating unit, and/or the third repeating unit, will increase the hydrophilicity of the photosensitive polymer in the first region 132 of the photoresist film 130. Thus, the solubility of the first region 132 with respect to the developing solution may increase. Meanwhile, solubility to the developing solution will be low in the second region 134 of the photoresist film 130. This is because the first repeating unit, the second repeating unit, and/or the third repeating unit of the photosensitive polymer of the second region 134 has not undergone the deprotection reaction, and so the photosensitive polymer is relatively hydrophobic.

Therefore, during the development of the photoresist film 130 using the developing solution, the first region 132 may be cleanly removed, and a vertical sidewall profile may be obtained in the photoresist pattern 130P. As described above, since the profile of the photoresist pattern 130P is improved, when a feature layer 110 is processed using the photoresist pattern 130P, a critical dimension of a processing region (e.g., the phase between said first region 132 and said second region 134) intended in the feature layer 110 may be precisely controlled.

Referring to FIG. 1 and FIG. 2D, in process P40, in the resultant of FIG. 2C, the feature layer 110 may be processed using the photoresist pattern 130P.

To process the feature layer 110, various processes may be performed, such as: etching the feature layer 110 exposed through the opening OP of the photoresist pattern 130P; injecting an impurity ion to the feature layer 110; forming an additional film on the feature layer 110 through the opening OP; and/or transforming a portion of the feature layer 110 through the opening OP. In FIG. 2D, as an example process of processing the feature layer 110, a case where the feature layer 110 exposed through the opening OP is etched to form a feature pattern 110P, is exemplified.

In other embodiments, in the processes described with reference to FIG. 2A, the process of forming the feature layer 110 may be omitted. In this case, the substrate 100 may be processed using the photoresist pattern 130P instead of the process described above with reference to process P40 in FIG. 1 and FIG. 2D. For example, various processes may be performed, such as: etching a portion of the substrate 100 using the photoresist pattern 130P; injecting an impurity ion into a portion of the substrate 100; forming an additional film on the substrate 100 through the opening OP; and/or transforming a portion of the substrate 100 through the opening OP.

Referring to FIG. 2E, in the resultant in FIG. 2D, the photoresist pattern 130P and the DBARC pattern 120P, which are remained on the feature pattern 110P, may be removed. In order to remove the photoresist pattern 130P and the DBARC pattern 120P, ashing and strip processing may be used.

Accordingly, methods of manufacturing the integrated circuit device as described with reference to FIG. 1 and FIG. 2A to FIG. 2E may increase the dissolution contrast. Specifically, the dissolution contrast may increase as a result of applying the developing solution to the exposed region and the non-exposed region of the photoresist film 130 obtained using a photoresist composition according to the present invention. As a result, LER and/or LWR may decrease in the photoresist pattern 130P obtained from the photoresist film 130, and thus high pattern fidelity may be provided. Therefore, when the subsequent process is performed for the feature layer 110 and/or substrate 100 using the photoresist pattern 130P, dimensional precision may be improved by precisely adjusting the critical dimension of processing regions or patterns desired to form on the feature layer 110 and/or the substrate. In addition, a critical dimension (DC) distribution of patterns desired to achieve on the substrate 100 may be uniformly controlled, and productivity of the manufacturing process of the integrated circuit device may be improved.

As described above, embodiments have been described in the specifications with reference to the drawings. Although the embodiments have been described using specific terms in this specification, they are only used for the purpose of explaining the technical idea of the inventive concept and are not used to limit the scope of the inventive concept described in the claims. Therefore, it should be understood that various changes, modifications, and other equivalent embodiments can be made by one ordinary skilled in the art. Therefore, the true technical protection scope of the inventive concept should be determined by the technical spirit of the following claims.

While the inventive concept has been particularly shown and described with reference to embodiments thereof, it will be understood that various changes in form and details may be made therein without departing from the spirit and scope of the following claims.

What is claimed is:

1. A photoresist composition comprising:
a photosensitive polymer;
a photoacid generator (PAG); and
a solvent,
wherein the photosensitive polymer comprises a sulfonate group (—SO₂O—) bonded with an α-trifluoromethylbenzyl group that is substituted or unsubstituted.

2. The photoresist composition of claim 1, wherein the α-trifluoromethylbenzyl group is substituted with a substituent and the benzene ring of the α-trifluoromethylbenzyl group comprises the substituent bonded at an ortho-position with respect to the position of the trifluoromethyl of the benzene ring.

3. The photoresist composition of claim 1, wherein the α-trifluoromethylbenzyl group is substituted with a substituent and the benzene ring of the α-trifluoromethylbenzyl group comprises the substituent bonded at a meta-position with respect to the position of the trifluoromethyl of the benzene ring.

4. The photoresist composition of claim 1, wherein the α-trifluoromethylbenzyl group is substituted with a substituent and the benzene ring of the α-trifluoromethylbenzyl group comprises the substituent bonded at a para-position with respect to the position of the trifluoromethyl of the benzene ring.

5. The photoresist composition of claim 1, further comprising a basic quencher.

6. The photoresist composition of claim 1, further comprising a surfactant, dispersant, desiccant, and/or coupling agent.

7. A photoresist composition comprising:
a photosensitive polymer;
a photoacid generator (PAG); and
a solvent,
wherein the photosensitive polymer includes a first repeating unit according to Formula 1-1: 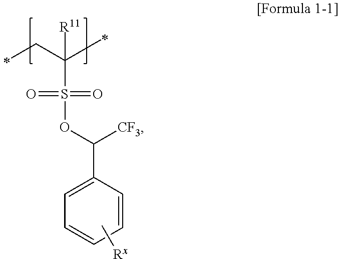
a second repeating unit according to Formula 2-1: 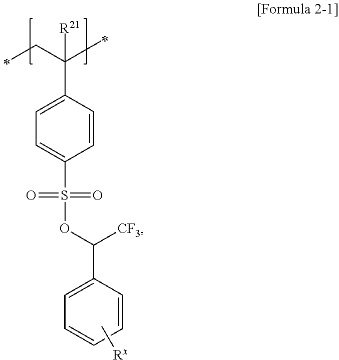
and
a third repeating unit according to Formula 3-1: 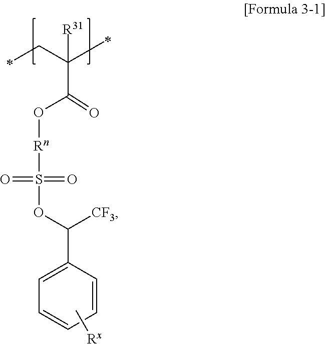
wherein:
R¹¹, R²¹, and R³¹ are each independently a hydrogen atom or a methyl group;
Rⁿ is a C1-C30 alkyl group;
each R^{x} is independently selected from the group consisting of hydrogen, a methyl group, an isopropyl group (iPr), a tert-butyl (tBu) group, an ethyl group, a phenyl group (Ph), chlorine (Cl), bromine (Br), iodine (I), and a methoxy group; and
* is a binding site.

8. The photoresist composition of claim 7, wherein the photosensitive polymer includes a structure according to Structural Formula 1: 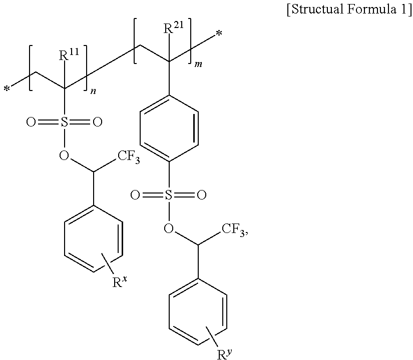
wherein, in Structural Formula 1:
R¹¹ and R²¹ are each independently a hydrogen atom or a methyl group;
R^{x} and R^{y} are each independently selected from the group consisting of hydrogen, a methyl group, an isopropyl group (iPr), tert-butyl (tBu) group, an ethyl group, a phenyl group (Ph), chlorine (Cl), bromine (Br), iodine (I), and a methoxy group;
* is a binding site; and
n/(n+m) is 0.2 to 0.8.

9. The photoresist composition of claim 7, wherein the photosensitive polymer includes a structure according to Structural Formula 2: 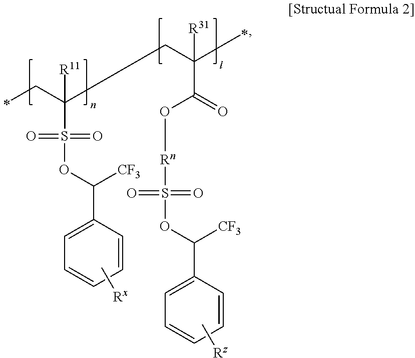
wherein, in Structural Formula 2:
R¹¹ and R³¹ are each independently a hydrogen atom or a methyl group;
R^{x} and R^{z} are each independently selected from the group consisting of hydrogen, a methyl group, an isopropyl group (iPr), tert-butyl (tBu) group, an ethyl group, a phenyl group (Ph), chlorine (Cl), bromine (Br), iodine (I), and a methoxy group;
Rⁿ is a C1-C30 alkyl group
* is a binding site; and
n/(n+l) is 0.2 to 0.8.

10. The photoresist composition of claim 7, wherein the photosensitive polymer includes a structure according to Structural Formula 3: 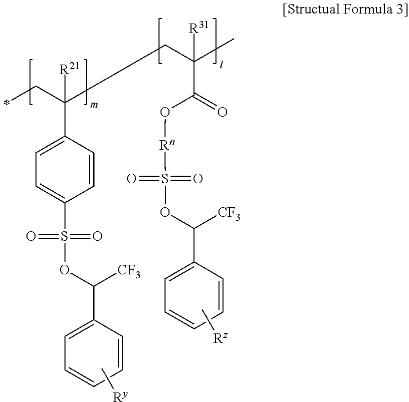
wherein, in Structural Formula 3:
R²¹ and R³¹ are each independently a hydrogen atom or a methyl group;
Rⁿ is a C1-C30 alkyl group;
R^{y} and R^{z} are each independently selected from the group consisting of hydrogen, a methyl group, an isopropyl group (iPr), tert-butyl (tBu) group, an ethyl group, a phenyl group (Ph), chlorine (Cl), bromine (Br), iodine (I), and a methoxy group;
* is a binding site; and
m/(m+l) is 0.2 to 0.8.

11. The photoresist composition of claim 7, wherein the photosensitive polymer includes a structure according to Structural Formula 4: 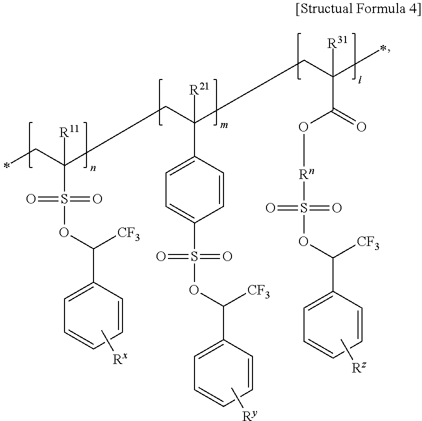
wherein, in Structural Formula 4:
R¹¹, R²¹, and R³¹ are each independently a hydrogen atom or a methyl group;
Rⁿ is a C1-C30 alkyl group;
R^{x}, R^{y}, and R^{z} are each independently selected from the group consisting of hydrogen, a methyl group, an isopropyl group (iPr), tert-butyl (tBu) group, an ethyl group, a phenyl group (Ph), chlorine (Cl), bromine (Br), iodine (I), and a methoxy group;
* is a binding site; and
n/(n+m+l) and m(n+m+l) are each independently 0.05 to 0.4.

12. The photoresist composition of claim 7, wherein the photosensitive polymer further includes a fourth repeating unit according to Formula 4: 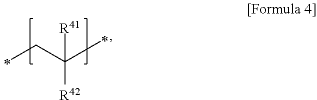
wherein, in Formula 4:
R⁴¹ is a hydrogen atom or a methyl group;
R⁴² is a C6-C30 aryl group comprising at least one hydroxy group or at least one methoxy group; and
* is a binding site.

13. The photoresist composition of claim 7, wherein, in each of Formula 1-1, Formula 2-1, and Formula 3-1, R^{x} is positioned at an ortho position as in the following structure:

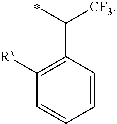

14. The photoresist composition of claim 7, wherein, in each of Formula 1-1, Formula 2-1, and Formula 3-1, R^{x} is positioned at a meta position as in the following structure:

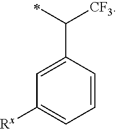

15. The photoresist composition of claim 7, wherein, in each of Formula 1-1, Formula 2-1, and Formula 3-1, R^{x} is positioned at a para position as in the following structure;

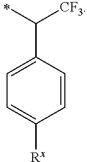

16. A method of manufacturing an integrated circuit device, the method comprising:
forming a photoresist film on a lower film using a photoresist composition comprising a photosensitive polymer, a photoacid generator (PAG), and a solvent; wherein the photosensitive polymer comprises a sulfonate group (—SO₂O—) bonded to an α-trifluoromethylbenzyl group that is substituted or unsubstituted;
generating a plurality of acids from the PAG by exposing a first region from a portion of the photoresist film to provide an exposed first region;
inducing a polarity change of the photosensitive polymer through a deprotection reaction of the α-trifluoromethylbenzyl group using the plurality of acids;
removing the exposed first region from the photoresist film using a developing solution to form a photoresist pattern that is formed by a non-exposed region of the photoresist film; and
processing the lower film using the photoresist pattern.

17. The method of claim 16, wherein, in the forming of the photoresist film on the lower film by using the photoresist composition, the photosensitive polymer includes a first repeating unit, a second repeating unit, or a third repeating unit, and wherein the first repeating unit comprises a structure according to Formula 1-1: 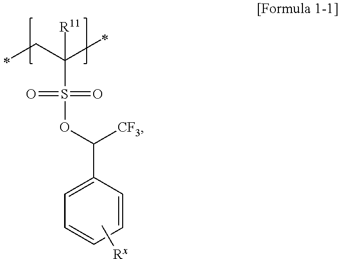
the second repeating unit comprises a structure according to Formula 2-1: 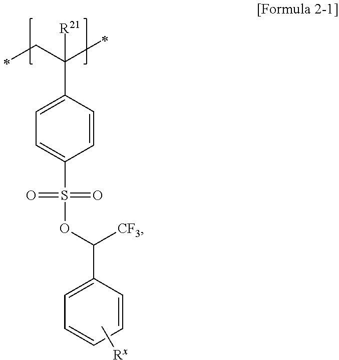
and
the third repeating unit comprises a structure according to Formula 3-1: 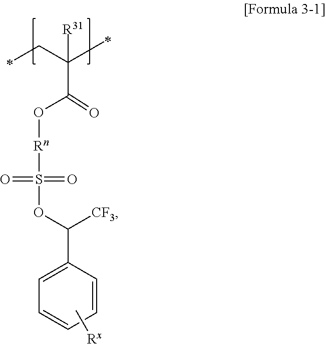
wherein:
R¹¹, R³¹, and R³¹ are each independently a hydrogen atom or a methyl group;
Rⁿ is a C1-C30 alkyl group;
each R^{x} is independently selected from the group consisting of hydrogen, a methyl group, an isopropyl group (iPr), a tert-butyl (tBu) group, an ethyl group, a phenyl group, chlorine (Cl), bromine (Br), iodine (I), and a methoxy group; and
* is a binding site.

18. The method of claim 16, wherein, in the forming of the photoresist film on the lower film using the photoresist composition, the photosensitive polymer further comprises a repeating unit according to Formula 4: 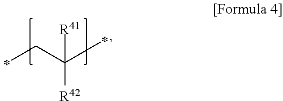
wherein, in Formula 4:
R⁴¹ is a hydrogen atom or a methyl group;
R⁴² is a C6-C30 aryl group including at least one hydroxy group or at least one methoxy group;
and * is a binding site.

19. The method of claim 16, wherein, in the forming of the photoresist film on the lower film using the photoresist composition, the photosensitive polymer further comprises a structure according to Structural Formula 5: 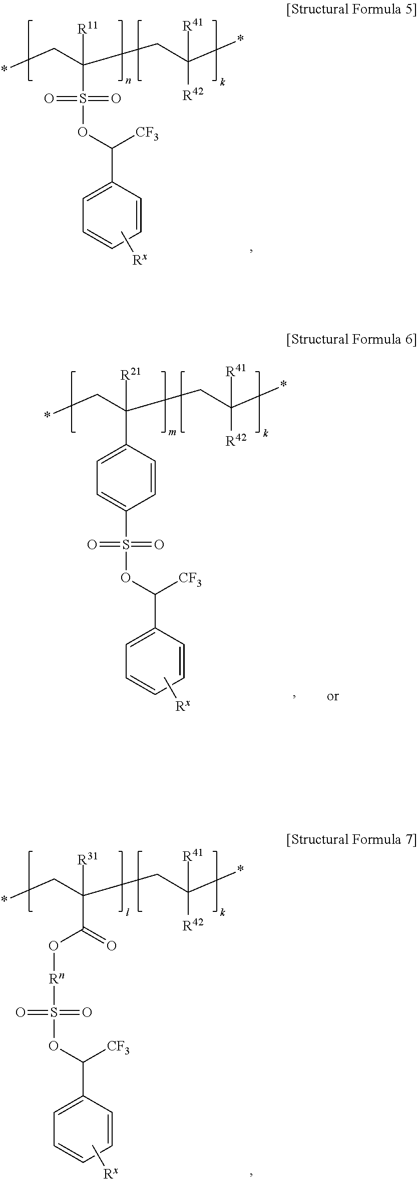
wherein:
R¹¹, R²¹, R³¹, and R⁴¹ are each independently a hydrogen atom or a methyl group;
R^{x} is selected from the group consisting of hydrogen, a methyl group, an isopropyl group (iPr), a tert-butyl (tBu) group, an ethyl group, a phenyl (Ph) group, chlorine (Cl), bromine (Br), iodine (I), and a methoxy group;
R⁴² is a C6-C30 aryl group including at least one hydroxy group or at least one methoxy group;
* is a binding site;
l/(l+k) is 0.2 to 0.8;
m/(m+k) is 0.2 to 0.8; and
n/(n+k) is 0.2 to 0.8.

20. The method of claim 16, wherein, in the forming of the photoresist film on the lower film using the photoresist composition, the photosensitive polymer includes, as a repeating unit, the PAG or a photodegradable base.
